(19) United States
(12) Patent Application Publication
(10) Pub. No.: US 2005/0226045 A1
(43) Pub. Date: Oct. 13, 2005

(54) HOT CHANNEL DISTRIBUTION BLOCK FOR CONNECTION TO AN INJECTION MOLDING MACHINE

(75) Inventor: Michael Goinski, Rimpar (DE)

Correspondence Address: ARTZ & ARTZ, P.C., 28333 TELEGRAPH RD., SUITE 250, SOUTHFIELD, MI, 48034, US

(73) Assignee: INCOE CORPORATION, Troy, MI (US)

(21) Appl. No.: 10/904,684

(22) Filed: Nov. 23, 2004

(30) Foreign Application Priority Data
Apr. 10, 2004 (DE) 20 2004 005 722 0

(51) Int. Cl. G11C 16/06

(52) U.S. Cl. 365/185.2

(57) ABSTRACT

Hot-channel distribution block for connection to an injection molding machine, to which hot-channel distribution block injection nozzles capable of insertion into a tool are fastened. At least one assembly centering pin, which is capable of introduction into an assembly centering hole in the tool and which projects farther in the direction of the tool than the injection nozzle projecting farthest in this direction, is fastened to the hot-channel distribution block.

### TECHNICAL FIELD

The present invention relates to a hot-channel distribution block for connection to an injection molding machine, to which hot-channel distribution block injection nozzles capable of introduction into a tool are fastened.

### BACKGROUND

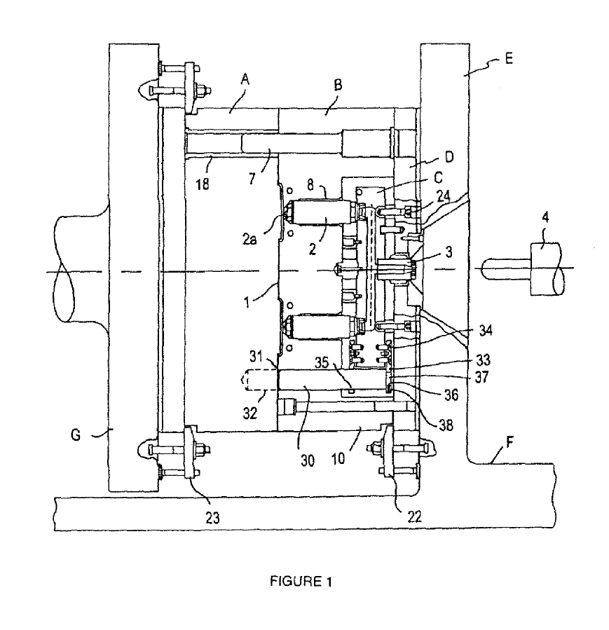

For injection molding of objects in an injection molding tool (injection mold), the injection nozzles, which are fastened to the hot-channel distribution block, must be introduced into the tool and then the tool and the hot-channel distribution block with the nozzles must be connected to the injection molding machine. In order to make this operation more understandable, reference is made to FIG. 1, which shows the above-mentioned parts in section and in the fixed state in the injection molding machine.

The tool consists of the tool injection part B and the tool ejection part A. The plane of separation between the two tool halves is labeled 1. Numeral 5 designates the cavities in the tool, into which the melt is injected for forming the object to be molded. The nozzles 2 are connected via a hot-channel distribution block C and a connection bushing 3 to the injection molding machine F. The aforesaid three structural elements 2, C and 3 are called the hot-channel distribution system.

This hot-channel distribution system is fixed by a plurality of bolts 10 between the tool injection part B and the head plate D. In addition, the hot-channel distribution system may be connected by the bolt 24 with the head plate D. The connection to the injection molding machine F is effected by means of the clamps 22 to the fixed machine plate E. The injection molding machine F with its injection cylinder 4 is indicated only summarily in the figure. The tool ejection part A is fastened by means of the clamps 23 to the machine plate G of the injection molding machine F, capable of horizontal displacement in the sense of the drawing. Guide bolts 7, which are introduced from the injection-machine side into the two halves of the tool, serve for centering the two tool halves. The accommodating bores for the guide bolts 7 in the tool halves are lined with bushings 18 of material capable of easy sliding.

In the exemplary embodiment shown, the hot-channel distribution system, comprised of the nozzles 2, the hot-channel distribution block C and the injection bushing 3, is designed in what is known as compact fashion, which means that the nozzles 2 are firmly connected with the hot-channel distribution block C, for example by bolting, and the system is wired ready for connection. Such a hot-channel distribution system designed in compact fashion thus represents a closed unit, on which all electrical and hydraulic connections have already been made and which can be tested as such before its assembly.

The system thus far described is part of the related art, and is also described in patent application DE 101 51 693. In the embodiment described in DE 101 51 693, for reasons of easier accessibility of the hot-channel distribution system, the bolts 10 are introduced from the plane-of-separation side of the tool injection part B. For the present invention, however, this type of connection between tool injection part B and head plate D is not material. In the present invention, the bolts 10 may just as well be introduced for example from the side of the head plate D.

Known hot-channel distribution system shown in the figure has the following disadvantages. Upon mounting of tool and hot-channel distribution system on the injection molding machine, the hot-channel distribution system, hanging on a hoisting device, is lowered from above into the tool injection part B located in horizontal position. Accordingly, strict attention must be taken to see that the nozzles 2 open into the corresponding bores 8 in the tool injection part B in order to prevent damage to the nozzles, in particular their sensitive precision-finished tips 2a for the gate region, by bumping against the tool injection part. This risk is further increased in that when the hot-channel distribution system is lowered, it frequently hangs somewhat inclined on the hoist.

An additional disadvantage of known hot-channel distribution systems consists in that they cannot be set down on a support by the nozzle side, since the risk of damage to the nozzle tips 2a is very great. The guide bolts 7 cannot prevent this, since the hot-channel distribution system is assembled earlier in time than the head plate D and therefore the guide bolts 7 do not yet have a firm hold in their longitudinal direction.

### SUMMARY OF THE INVENTION

The object of the invention is to refine a hot-channel distribution block, to which the injection nozzles to be introduced into the tool are fastened, in such a way that the aforesaid risks of damage to the nozzles are avoided.

To accomplish this object, a unique hot-channel distribution block for connection to an injection molding machine is provided. The injection nozzles capable of introduction into a tool are fastened to the block. One or more assembly centering pins, which are capable of introduction into assembly centering holes in the tool and which project farther in the direction of the tool than the injection nozzles projecting farthest in this direction, are fastened to the hot-channel distribution block. In an alternate embodiment, at least three of the said assembly centering pins and three of the said assembly centering holes are provided. Also, the length of the assembly centering pins can be sized so that when the hot-channel distribution block is inserted into the tool they do not project beyond the plane of separation of the tool.

### BRIEF DESCRIPTION OF THE DRAWING

The invention is described in detail by means of the exemplary embodiment shown in FIG. 1.

### DESCRIPTION OF THE PREFERRED EMBODIMENTS

According to the invention, at least one assembly/assembly/built-in/centering pin 30 is fastened directly to the hot-channel distribution block C. This may be done for example, as shown in the exemplary embodiment, by two straps 33, which by their one end are held fast by the screws 34 to the hot-channel distribution block C and at their other ends accommodating holes 35, 36 are provided for the assembly centering pin 30. In order to obtain good seating of the centering pin 30 in the straps 33 and to avoid longitudinal displacement of the centering pin, the hole 36 has a small diameter on the strap 33 on the side of the hot-channel distribution block turned away from the nozzles, and the centering pin 30 is provided at the associated end with a corresponding shoulder 37. A stop screw 38 arrests the assembly centering pin 30 in its position.

It is understood that the fastening of the assembly centering pin 30 may be formed on the hot-channel distribution block C in any other way desired, such as for example alternatively by welding.

Thanks to the fact that the centering pins 30 project farther than the nozzles 2 in the direction of the tool ejection part A from the hot-channel distribution block C, the above-mentioned disadvantages of the known hot channel distribution systems are avoided. Upon lowering of the hot-channel distribution system for introduction of the injection nozzles into the tool, the assembly centering pins 30 are first set on the tool, and when they have found their entry into the assembly centering holes 31 the nozzles are then securely introduced into the tool injection part B. As a result, construction is substantially facilitated and accelerated.

In addition, the hot-channel distribution system can now be set on a support by the nozzle side without risk of damage to the nozzles, since then it comes to stand on the non-sensitive assembly centering pins.

In the exemplary embodiment shown, the centering pin 30 does not project beyond the plane of separation 1 in the direction of the tool ejection part A. However, according to the invention the centering pin 30 may alternatively be designed longer than as shown in the FIG. 1, where a corresponding assembly centering hole 32, indicated by a broken line, must then be provided in the tool ejection part. In such an embodiment, the centering pin 30 may alternatively serve for centering of the two tool halves A, B. However, this form of tool centering is not very exact, since the centering pin 30, due to its direct connection with the hot hot-channel distribution block C, participates in the thermal expansions caused by operation and therefore the centering holes 31 and 32 must be designed with a relatively large tolerance, for example 1 mm. For this reason, as a rule the centering bolts 7 are in addition used for centering of the two tool halves, which do not participate in the thermal expansions of the hot-channel distribution block C. The centering pins 30 projecting beyond the plane of separation 1 then have the function of pre-centering the two tool halves.

While particular embodiments of the invention have been shown and described, numerous variations and alternate embodiments will occur to those skilled in the art. Accordingly, it is intended that the invention be limited only in terms of the appended claims.

1. Hot-channel distribution block for connection to an injection molding machine, to which hot-channel distribution block injection nozzles capable of introduction into a tool are fastened, said block comprising at least one assembly centering pin, which is capable of introduction into an assembly centering hole in the tool and which projects farther in the direction of the tool than the injection nozzle projecting farthest in that direction, is fastened to the hot-channel distribution block (C).

2. The hot-channel distribution block according to claim 1, wherein at least three of the said assembly centering pins and three of the said assembly centering holes are provided.

3. Hot-channel distribution block according to claim 1 wherein the length of the assembly centering pins is sized so that when the hot-channel distribution block is inserted into the tool they do not project beyond the plane of separation of the tool.

4. Hot-channel distribution block according to claim 2 wherein the length of the assembly centering pins is sized so that when the hot-channel distribution block is inserted into the tool they do not project beyond the plane of separation of the tool.

5. The hot-channel distribution block according to claim 1, wherein the length of the assembly centering pins are sized so that, for the purpose of pre-centering the tool halves when the hot-channel distribution block is introduced into the tool, they each project into an assigned recess of the ejection-side tool part.

6. The hot-channel distribution block according to claim 2, wherein the length of the assembly centering pins is sized so that, for the purpose of pre-centering the tool halves when the hot-channel distribution block is introduced into the tool, they each project into an assigned recess of the ejection-side tool part.

7. The hot-channel distribution block according to claim 1 wherein the assembly centering pin is bolted on laterally by straps to the hot-channel distribution block.

8. The hot-channel distribution block according to claim 2 wherein the assembly centering pin is bolted on laterally by straps to the hot-channel distribution block.
